(19) United States
(12) Patent Application Publication
(10) Pub. No.: US 2019/0230814 A1
(43) Pub. Date: Jul. 25, 2019

(54) AIR BLOWER

(71) Applicant: Nidec Corporation, Kyoto (JP)

(72) Inventors: Koji HATANAKA, Kyoto (JP); Takehito TAMAOKA, Kyoto (JP); Kazuhiko FUKUSHIMA, Kyoto (JP)

(21) Appl. No.: 16/238,543

(22) Filed: Jan. 3, 2019

(30) Foreign Application Priority Data
Jan. 19, 2018 (JP) 2018-007245

(51) Int. Cl. H05K 7/20; F04D 13/06; F04D 29/42; F28D 15/02; G06F 1/20

(52) U.S. Cl. CPC H05K 7/20172; F04D 13/0606; F04D 29/4213; F04D 29/422; G06F 2200/201; H05K 7/20336; H05K 7/20154; G06F 1/203; F28D 15/0275

(57) ABSTRACT

In an air blower, an exhaust includes fins and extends in a first direction that is a radial component of an impeller. Assuming that a first virtual circle is a circle connecting ends on a side opposed to the impeller in a fin group in a first direction, and that a second virtual circle is a circle larger than a virtual circle connecting radially outer edges of blades of the impeller with a central axis as a center in diameter and is connected to the first virtual circle at one point, a radius of the first virtual circle is larger than a radius of the second virtual circle.

### CROSS REFERENCE TO RELATED APPLICATIONS

This application claims the benefit of priority to Japanese Patent Application No. 2018-007245 filed on Jan. 19, 2018. The entire contents of this application are hereby incorporated herein by reference.

### BACKGROUND OF THE INVENTION

### 1. Field of the Invention

The present disclosure relates to an air blower.

### 2. Description of the Related Art

Conventionally, there have been known various air blowers. For example, a heat sink for a semiconductor device is disclosed.

The conventional heat sink for a semiconductor device includes a fin group and a blower fan. The fin group has a shape in which a large number of plates or pins are vertically arrayed on a base. The blower fan includes a fan rotating mechanism and a centrifugal fan. The fin group and the centrifugal fan each include a cover. An air intake port is disposed in the cover of the centrifugal fan in a rotational direction.

However, in the plurality of conventional fins, because fin ends of on a side opposed to the centrifugal fan are connected to each other in a linear shape extending in a direction orthogonal to the direction in which the centrifugal fan and the fin are opposed to each other, a distance between an outer edge of the centrifugal fan and the fin end is increased, and a wind pressure is decreased to decrease air blowing force to the fins. Additionally, because the fin ends are linearly connected to each other, it cannot be said that a plane area that is an area of the linear portion is sufficiently large, and air blowing efficiency may be reduced.

### SUMMARY OF THE INVENTION

According to one aspect of the present disclosure, an air blower includes an impeller centered on a central axis extending in a vertical direction, a motor that rotates the impeller about the central axis, and a housing that accommodates the impeller. The housing includes a lower plate which covers a lower side of the impeller and to which the motor is fixed, a side wall that covers a side of the impeller, and an upper plate that covers an upper side of the impeller. At least one of the upper plate and the lower plate includes an air intake portion. An exhaust is disposed in a first direction that is a radial component of the impeller. The exhaust includes a plurality of fins. Assuming that a first virtual circle is a circle connecting the ends on a side opposed to the impeller in a fin group that is a part of the plurality of fins in a first direction, and that a second virtual circle is a circle, which is larger than a virtual circle connecting radially outer edges of a plurality of blades of the impeller with the central axis as a center in diameter and is connected to the first virtual circle at one point, a radius of the first virtual circle is larger than a radius of the second virtual circle.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a sectional view illustrating an air blower according to an exemplary embodiment of the present disclosure.

FIG. 2 is a plan view illustrating an air blower of an exemplary embodiment of the present disclosure.

FIG. 3 is a plan view illustrating an air blower having an exhaust according to a first modification of an exemplary embodiment of the present disclosure.

FIG. 4 is a plan view illustrating an air blower having an exhaust unit according to a second modification of an exemplary embodiment of the present disclosure.

FIG. 5 is a plan view illustrating a configuration example of an air blower with a heat pipe.

FIG. 6 is a plan view illustrating an air blower according to a third modification of an exemplary embodiment of the present disclosure.

### DETAILED DESCRIPTION OF THE PREFERRED EMBODIMENTS

Exemplary embodiments of the present disclosure will be described below with reference to the drawings. In this specification, a direction in which a central axis C1 (to be described later) extends is referred to as a “vertical direction”. However, the “vertical direction” does not indicate a vertical direction when the air blower is installed in an actual device. A radial direction about the central axis C1 is simply referred to as a “radial direction”, and a circumferential direction about the central axis C1 is simply referred to as a “circumferential direction”. The “vertical direction” is occasionally referred to as an “axial direction”.

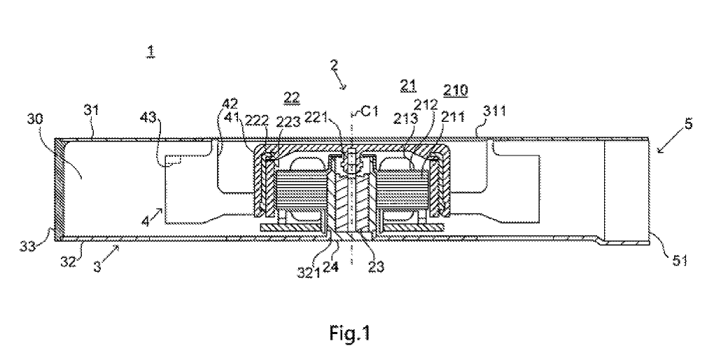

FIG. 1 is a sectional view illustrating an air blower 1 according to an exemplary embodiment of the present disclosure. The air blower 1 is a centrifugal fan. For example, the air blower 1 is installed in a notebook personal computer (PC), and used to cool components in a casing of the notebook PC.

The air blower 1 includes a motor unit 2, a housing 3, and an impeller 4. The impeller 4 is centered on the central axis C1 extending in the vertical direction. The motor unit 2 rotates the impeller 4 about the central axis C1. The housing 3 accommodates the motor unit 2 and the impeller 4.

The housing 3 includes an upper plate 31, a lower plate 32, and a side wall 33. The upper plate 31 covers an upper side of the impeller 4. The lower plate 32 covers a lower side of the impeller 4. The side wall 33 covers a side of the impeller 4. The motor unit 2 is fixed to the lower plate 32. The upper plate 31, the side wall 33, and the lower plate 32 constitute a wind tunnel 30 surrounding the impeller 4.

The upper plate 31 and the lower plate 32 are formed into a thin sheet shape made of metal such as an aluminum alloy and a stainless steel. The side wall 33 is formed from a die-cast aluminum alloy or resin. A lower end of the side wall 33 is fixed to a periphery of the lower plate 32 by, for example, screwing. The upper plate 31 is fixed to an upper end of the side wall 33 by, for example, caulking.

As illustrated in FIG. 1, the motor unit 2 is of an outer rotor type. The motor unit 2 includes a stationary unit 21, a rotating unit 22, and a sleeve 23 serving as a bearing. The sleeve 23 has a substantially cylindrical shape centered on the central axis C1. The rotating unit 22 can be rotated about the central axis C1 with respect to the stationary unit 21 by a shaft 221 (to be described later) and the sleeve 23.

The stationary unit 21 includes a stator 210 and a bearing holder 24. The bearing holder 24 accommodates the sleeve 23. The bearing holder 24 has a substantially cylindrical shape centered on the central axis C1, and is made of resin. The bearing holder 24 protrudes upward from the lower plate 32. The bearing holder 24 is fixed to a hole 321 made in the lower plate 32. The lower end of the bearing holder 24 and a peripheral portion of the hole 321 are fastened by, for example, insert molding. The fixing between the lower end of the bearing holder 24 and the peripheral portion of the hole 321 is not limited to the insert molding, but the lower end of the bearing holder 24 and the peripheral portion of the hole 321 may be fixed by press-fitting or caulking.

The stator 210 has an annular shape centered on the central axis C1, and is installed to an outer circumferential surface of the bearing holder 24. The stator 210 includes a stator core 211, an insulator 212, and a coil 213. The stator core 211 is formed by laminating thin electromagnetic steel sheets. An inner circumferential surface of the stator core 211 is fixed to the outer circumferential surface of the bearing holder 24. The insulator 212 covers the surface of the stator core 211.

The rotating unit 22 includes a shaft 221, a yoke 222, and a rotor magnet 223. The shaft 221 is a rod-shaped member that extends in the vertical direction while being centered on the central axis C1. The upper end of the shaft 221 is fixed to a cup 41 (described later) of the impeller 4. The yoke 222 has a substantially cylindrical shape centered on the central axis C1, and is fixed to an inner surface of the cup 41. The rotor magnet 223 has a substantially cylindrical shape centered on the central axis C1, is fixed to the inner surface of the yoke 222, and is opposed to the stator 210 in the radial direction.

The shaft 221 is inserted into the sleeve 23. The outer circumferential surface of the shaft 221 is opposed to the inner circumferential surface of the sleeve 23 with a space therebetween. The sleeve 23 is made of an oil-containing porous metal body, and inserted into and fixed to the bearing holder 24. The bearing may be a ball bearing.

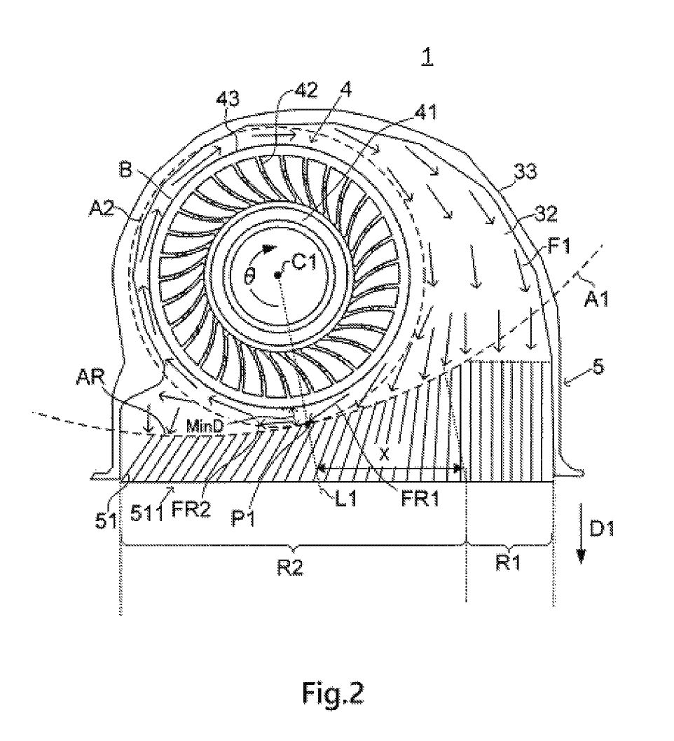

FIG. 2 is a plan view illustrating the air blower 1 viewed from above. In FIG. 2, the upper plate 31 is not illustrated for the sake of convenience. The impeller 4 includes the cup 41, a plurality of blades 42, and a coupling unit 43. The cup 41, the blades 42, and the coupling unit 43 are made of resin into a single member. As illustrated in FIG. 2, a rotational direction θ of the impeller 4 is clockwise as when the impeller 4 is viewed from above.

The cup 41 has a covered substantially cylindrical shape centered on the central axis C1, and is open downward. The plurality of blades 42 extend radially outward from the outer circumferential surface of the cup 41. The blades 42 are arranged at equal intervals in the circumferential direction. An outer circumferential end of each blade 42 is disposed behind an inner circumferential end of the blade 42 in the rotational direction. Consequently, the blade 12 is inclined with respect to the radial direction.

The coupling unit 43 is formed into an annular shape by coupling top surfaces of the outer circumferential ends of the blades 42 adjacent in the circumferential direction. Although not illustrated in FIG. 2 but illustrated in FIG. 1, the upper plate 31 is provided with an air intake hole 311 as an air intake portion. The air intake hole 311 is located above the impeller 4. An inner peripheral edge of the coupling unit 43 is disposed radially outside the air intake hole 311. Thus, from the air blower 1, the impeller 4 is exposed through the air intake hole 311 as viewed from above.

The air intake hole may be disposed in the lower plate 32 instead of the upper plate 31, or in both of the upper plate 31 and the lower plate 32. In the case where the air intake hole is provided in the lower plate 32, a plurality of air intake holes are disposed around the central axis C1 in the circumferential direction. That is, at least one of the upper plate 31 and the lower plate 32 may include the air intake portion.

As illustrated in FIG. 2, the air blower 1 includes an exhaust unit 5 disposed in a first direction D1 that is a radial component of the impeller 4. For example, the exhaust unit 5 is formed by a part of the lower plate 32, a plurality of fins 51, and part of the upper plate 31 (not illustrated in FIG. 2). The plurality of fins 51 are arrayed in a direction perpendicular to the first direction D1. The fin 51 is a plate-shaped member, which is vertically sandwiched between the upper plate 31 and the lower plate 32 and stands in the vertical direction. A part of the fins 51 may not be sandwiched between the upper plate 31 and the lower plate 32.

In the case where a heat pipe is disposed above the fins 51 as described later, the upper plate 31 extends to an edge of the heat pipe on an opposite side to the first direction D1. In this case, the exhaust unit 5 is formed by a part of the lower plate 32, a plurality of fins 51, and the heat pipe. The exhaust unit 5 may be made of a material different from that of the upper plate 31 and the lower plate 32. The heat pipe may be disposed above the fins 51 with the upper plate 31 interposed therebetween.

When electric current is supplied to the coil 213, torque about the central axis C1 is generated between the rotor magnet 223 and the stator 210. This enables the impeller 4 to rotate about the central axis C1 in the rotational direction θ. When the impeller 4 rotates, air flows into the housing 3 through the air intake hole 311. The air that has flowed into the housing 3 flows between the adjacent blades 42, and accelerates radially outward along the blade 42. The air that has accelerated radially outward is blown radially outward of the impeller 4. The air that has been blown radially outward of the impeller 4 flows in the wind tunnel 30, and is discharged outward through a gap between the adjacent fins 51.

A more specific configuration of the exhaust unit 5 will be described below with reference to FIG. 2. In FIG. 2, the flow of air generated by the rotation of the impeller 4 is expressed as an airflow F1.

It is assumed that a first virtual circle A1 is a circle connecting ends on the side opposed to the impeller 4 in a fin group 511 that is a part of the plurality of fins 51 in the first direction D1, namely, ends on the air inflow side. It is also assumed that a virtual circle B is a circle connecting the radially outer edges of the plurality of blades 42 with the central axis C1 as the center, and that a second virtual circle A2 is a circle, which is larger than the virtual circle B in diameter and is concentric with the virtual circle B. The first virtual circle A1 is connected to the second virtual circle A2 at a virtual circle connection point P1 that is one point. A radius of the first virtual circle A1 is larger than a radius of the second virtual circle A2.

Consequently, as compared with the case where the radius of the first virtual circle A1 is identical to the radius of the second virtual circle A2, a distance between the outer edge of the blade 42 and the air-inflow-side end of the fin 51 in the fin group 511 is gradually changed, so that turbulence of the air can be prevented in a vicinity of the end of the fin 51. In other words, a noise of the air blower 1 can be reduced by preventing the turbulence of the air, and therefore the air blowing efficiency can be improved. The distance between the outer edge of the blade 42 and the end of the fin 51 is reduced as compared with the case where the air-inflow-side ends of the fin 51 are connected to each other into a linear shape extending in a direction orthogonal to the first direction D1, so that the wind pressure can be enhanced to improve the air blowing force of the air flowing into between the fins 51. That is, an amount of air blown from the exhaust unit 5 of the air blower 1 can be improved. As compared with the case where the ends of the fins 51 are connected linearly as described above, a plane area that is an area of the curved surface of an arc portion connecting the ends of the fins 51 located on the first virtual circle A1 is enlarged, and the air blowing efficiency and the cooling efficiency can be enhanced.

Although the inflow-side end of the fin 51 in a first region R1 (to be described later) is not located on the first virtual circle A1, all the ends of the plurality of fins 51 may be located on the first virtual circle A1. That is, a circle connecting all the ends of the plurality of fins 51 may be defined as the first virtual circle A1.

In other words, the air blower 1 of the present embodiment includes the impeller 4 centered on the central axis C1 extending in the vertical direction, the motor unit 2 that rotates the impeller 4 about the central axis C1, and the housing 3 that accommodates the impeller 4. The housing 3 includes the lower plate 32 which covers the lower side of the impeller 4 and to which the motor unit 2 is fixed, the side wall 33 that covers the side of the impeller 4, and the upper plate 31 that covers the upper side of the impeller 4. At least one of the upper plate 31 and the lower plate 32 includes the air intake portion (air intake hole 311).

The exhaust unit 5 is disposed in the first direction D1 that is the radial component of the impeller 4. The exhaust unit 5 includes the plurality of fins 51. Assuming that the first virtual circle A1 is the circle connecting the ends on the side opposed to the impeller 4 in the fin group 511 that is a part of the plurality of fins 51 in the first direction D1, and that the second virtual circle A2 is a circle, which is larger than the virtual circle B connecting the radially outer edges of the plurality of blades 42 of the impeller 4 with the central axis C1 as the center in diameter and is connected to the first virtual circle A1 at one point P1, the radius of the first virtual circle A1 is larger than the radius of the second virtual circle A2.

According to this configuration, the distance between the outer end of the blade 42 and the end of the fin 51 is gradually changed to prevent the turbulence of the air in the vicinity of the end of the fin 51, and a loss is reduced in the fin 51, so that the air volume of the air blower 1 can be increased and the noise of the air blower 1 can be reduced. By reducing the distance between the outer edge of the blade 42 and the end of the fin 51, the wind pressure can be enhanced to improve the air blowing force to the fins 51. The plane area of the fin 51 can be enlarged, and the air blowing efficiency and the cooling efficiency can be enhanced.

The distance between the outer edge of the blade 42 on a line segment extending in the radial direction from the central axis C1 and an arc AR connecting the air-inflow-side ends of the fins 51 in the fin group 511 is minimized at a distance MinD between the outer edge of the blade 42 on a first line segment L1, which extends from the central axis C1 and passes through the virtual circle connection point P1, and the arc AR. The distance MinD is a distance that can secure an area of the fin 51 and prevent a noise. For example, the distance MinD ranges from about 3 mm to about 5 mm.

The distance between the outer edge of the blade 42 and the end of the fin 51 is increased in an enlarged region FR1 located on an upstream side of the airflow F1 with respect to the position of the distance MinD and an enlarged region FR2 located on a downstream side of the airflow F1.

That is, assuming that the virtual circle connection point P1 is the connection point between the first virtual circle A1 and the second virtual circle A2, the distance between the radially outer end of the blade 42 and the arc AR connecting the ends of the fin group 511 is minimized in a region passing through the central axis C1 and the virtual circle connection point P1, and each of the upstream side and the downstream side of the airflow F1 generated by the rotation of the impeller 4 from the virtual circle connection point P1 includes enlarged regions FR1, FR2 where the distance between the radially outer end of the blade 42 and the end of the fin group 511 is increased.

Consequently, the distance between the outer end of the blade 42 and the end of the fin 51 is gradually changed to prevent the turbulence of the air in the vicinity of the end of the fin 51, and the loss is reduced in the fin 51, so that the air volume of the air blower 1 can be increased and the noise of the air blower 1 can be reduced.

At least a part of the fins 51 extends obliquely with respect to the line segment L1. That is, assuming that the first line segment L1 is a line segment connecting the central axis C1 and the virtual circle connection point P1, at least a part of the plurality of fins 51 extends in a direction inclined with respect to the first line segment L1.

Consequently, the fin 51 is obliquely disposed according to the direction of the airflow F1 flowing in a centrifugal direction, so that the loss can be reduced in the fins 51 to increase the amount air blown from the air blower 1.

As illustrated in FIG. 2, assuming that a first predetermined distance X is a distance from the line segment L1 toward the upstream side of the airflow F1 in the array direction of the fins 51, the plurality of fins 51 are divided into a first region R1 located on the upstream side of the first predetermined distance X and a second region R2 located on the downstream side of the first predetermined distance X. In the first region R1, the fins 51 extend in a direction orthogonal to the array direction of the fins 51. The airflow F1 flows in a direction substantially orthogonal to the array direction of the fins 51 on the inflow side of the first region R1, so that the loss can be prevented in the fins 51.

That is, assuming that the first predetermined distance X is the distance from the first line segment L1 toward the upstream side of the airflow F1 generated by the rotation of the impeller 4 in the array direction of the fins 51, at least a part of the plurality of fins 51 has the first region R1 located on the upstream side of the first predetermined distance X and the second region R2 located on the downstream side of the first predetermined distance X, and the fins 51 are arranged in the first region R1 while extending in the direction orthogonal to the array direction of the fins 51.

Consequently, by arranging the fins 51 of the first region R1 according to the direction of the airflow F1 flowing in the centrifugal direction, the loss can be reduced in the fins 51 to increase the air volume of the air blower 1.

In the first region R1, the end of the fin 51 is disposed on the radially outside of the first virtual circle A1. With increasing length of the fin 51, a flow resistance between the fins 51 is increased to increase the loss in the fin 51. For this reason, by reducing the length of the fin 51, the loss can be reduced in the fins 51 to increase the air volume.

As illustrated in FIG. 2, the fins 51 are arranged in the second region R2 such that the outflow-side end is inclined in a direction extending onto the downstream side of the airflow F1 with respect to the inflow-side end. The inclination angle is desirably set in a range of 0<inclination angle≤5 degrees when the inclination angle of the fin 51 in the first region R1 is set to 0 degrees.

That is, when the extending direction of the fin 51 arranged in the first region R1 is set to 0 degrees, the inclination angle of the fin 51 arranged in the second region R2 is set in the range of 0<inclination angle≤5 degrees. Consequently, the fin 51 is obliquely disposed according to the direction of the airflow F1 flowing in a centrifugal direction, so that the loss can be reduced in the fins 51 to increase the air volume of the air blower 1.

Preferably, the inclination angle of the fin 51 in the second region R2 is gradually changed from 0 to 5 degrees from the upstream side of the airflow F1 toward the downstream side. Consequently, the fin 51 is disposed with the finely-adjusted inclination according to the direction of the airflow F1 flowing in a centrifugal direction, so that the loss can further be reduced in the fins 51 to increase the air volume of the air blower 1. The inclination angle of the fin 51 may be changed in each predetermined region arranged in the second region R2 from the upstream side to the downstream side.

In FIG. 2, another region does not exist in a joint between the first region R1 and the second region R2. Alternatively, another region in which the fin is adjusted may be disposed in the joint unlike the first region R1 and the second region R2. That is, another region is not essential in the present disclosure relating to the first region R1 and the second region R2. The same holds true for the joint between the following other regions.

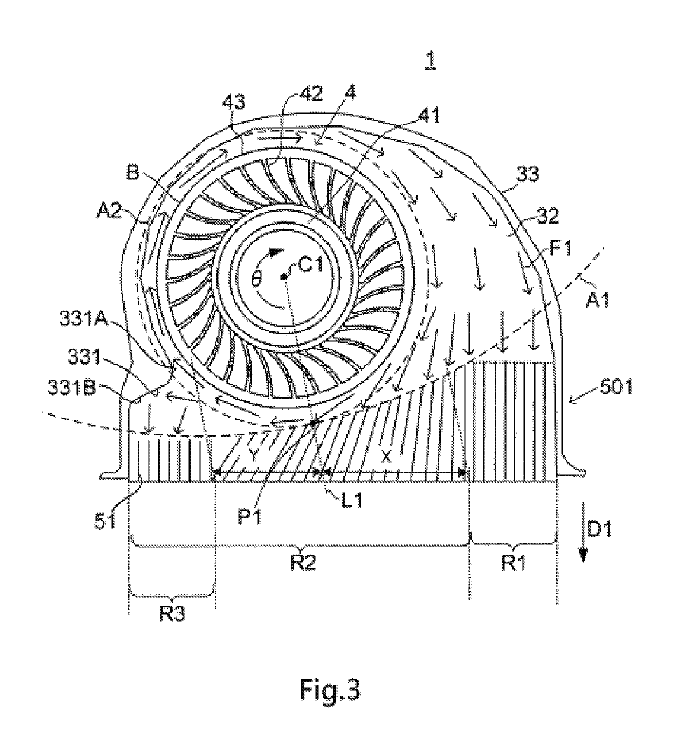

FIG. 3 is a plan view illustrating the air blower 1 including an exhaust unit 501 according to a first modification of the exhaust unit 5 of the embodiment described above. In the exhaust unit 501 of FIG. 3, it is assumed that a second predetermined distance Y is a distance from the line segment L1 toward the downstream side of the airflow F1 in the array direction of the fins 51. The second region R2 includes a third region R3 located on the downstream side of the second predetermined distance Y. The fins 51 arranged in the third region R3 extend in the direction orthogonal to the array direction of the fins 51, and extend in parallel to the extending direction of the fins 51 arranged in the first region R1.

That is, assuming that the second predetermined distance Y is the distance from the first line segment L1 toward the downstream side of the airflow generated by the rotation of the impeller 4 in the array direction of the fins 51, at least a part of the plurality of fins 51 of the second region R2 has the third region R3 located on the downstream side of the second predetermined distance Y, and the fins 51 are arranged in the third region R3 while extending in the direction orthogonal to the array direction of the fins 51.

Consequently, by arranging the fins 51 of the third region R3 according to the direction of the airflow F1 flowing in the centrifugal direction, the loss can be reduced in the fins 51 to increase the air volume of the air blower.

The side wall 33 has a tongue 331 protruding toward the impeller 4, and the tongue 331 is opposed to the third region R3 in the first direction D1 with a gap therebetween. By including the tongue 331, the air flow by the impeller 4 can be guided to the third region R3.

The tongue 331 includes a curved surface 331B from an apex 331A opposed to the impeller 4 toward the third region R3. The tongue 331 includes the curved surface 331B, so that the air flow by the impeller 4 can smoothly be guided to the third region R3.

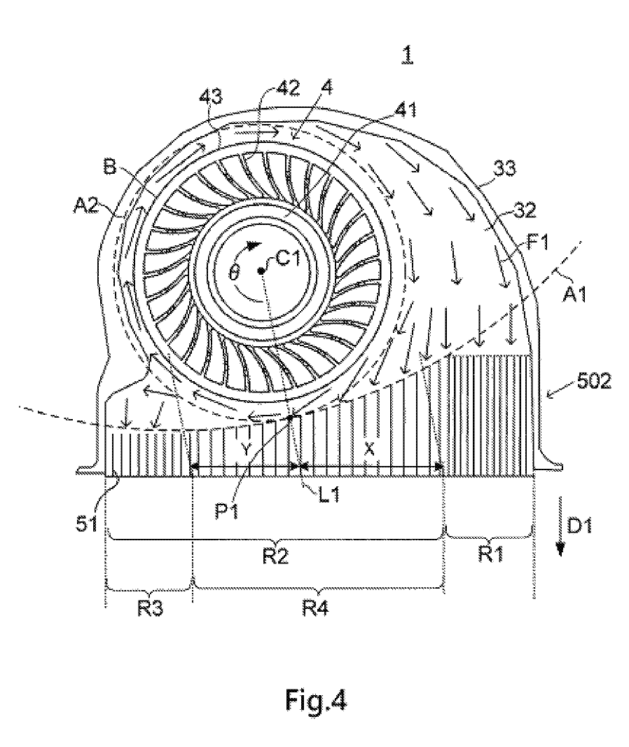

FIG. 4 is a plan view illustrating the air blower 1 including an exhaust unit 502 according to a second modification of the exhaust unit 5 of the embodiment described above. In the exhaust unit 502 of FIG. 4, all of the plurality of fins 51 are arranged while extending in the direction orthogonal to the array direction of the fins 51.

An interval between adjacent fins 51 in the second region R2 is larger than an interval between adjacent fins 51 in the first region R1. The interval between the fins 51 is reduced because the airflow F1 of the first region R1 flows in the direction substantially parallel to the extending direction of the fins 51, and the interval between the fins 51 is increased because the airflow F1 of the second region R2 flows in the direction inclined from or orthogonal to the extending direction of the fins 51, so that the air volume in the exhaust unit 502 can be equalized in the array direction of the fins 51.

That is, the interval between the fins 51 arranged in the second region R2 is larger than the interval between the fins 51 arranged in the first region R1, and the interval between the fins 51 is adjusted according to the direction of the air flowing in the centrifugal direction, so that a variation in the air volume can be prevented in the exhaust unit 502 to equalize the air volume in the array direction of the fins 51.

The interval between the adjacent fins 51 in the third region R3 is smaller than the interval between the adjacent fins 51 in a fourth region R4 that is a region in the second region R2 other than the third region R3. In the third region R3, the inclination in the flowing direction of the airflow F1 with respect to the extending direction of the fin 51 is smaller than that in the fourth region R4, so that the air volume can be equalized by reducing the interval between the fins 51 in the third region R3.

That is, assuming that the second predetermined distance Y is the distance from the first line segment L1 toward the downstream side of the airflow generated by the rotation of the impeller 4 in the array direction of the fins 51, at least a part of the plurality of fins 51 of the second region R2 has the third region R3 located on the downstream side of the second predetermined distance Y, and the interval between the fins 51 arranged in the third region R3 is smaller than the interval between the fins 51 arranged in the fourth region R4 included in the remaining region in the second region R2 other than the third region R3.

Consequently, by reducing the interval between the fins 51 in the third region R3 according to the direction of the airflow F1 flowing in the centrifugal direction, the air volume in the exhaust unit 502 can be equalized in the array direction of the fins 51.

The interval between the fins 51 in the predetermined region on the upstream side in the fourth region R4 of FIG. 4 may be identical to the interval between the fins 51 in the third region R3.

In the exhaust unit 5 of FIG. 2, the interval between the fins 51 in the second region R2 may be larger than the interval between the fins 51 in the first region R1.

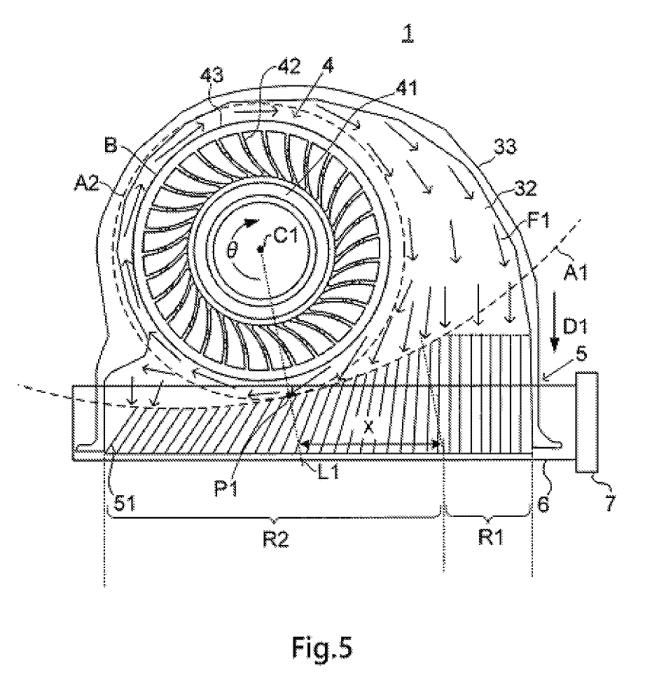

FIG. 5 is a plan view illustrating a configuration example of the air blower 1 in FIG. 2 with the heat pipe as viewed from above. FIG. 5 is a transparent view illustrating a lower configuration of the heat pipe 6 for the sake of convenience.

The air blower 1 in FIG. 5 includes the heat pipe 6. The heat pipe 6 extends in the array direction of the fins 51, and is disposed in contact with upper ends of the plurality of fins 51. The plurality of fins 51 are vertically sandwiched between the heat pipe 6 and the lower plate 32. The exhaust unit 5 includes the fins 51, the heat pipe 6, and the lower plate 32. In this case, the fin 51 may be made of metal. The upper plate 31 (not illustrated in FIG. 5) extends to a boundary between the upper plate 31 and the heat pipe 6.

The heat pipe 6 is a component that transfers heat generated from a heat source component 7 and cools the heat source component 7. An example of the heat source component 7 is a central processing unit (CPU). For example, the heat pipe 6 is a metal pipe containing a working fluid. The working fluid is evaporated by the heat generated from the heat source component 7. The evaporated working fluid moves in the heat pipe 6 toward the fins 51, and is cooled by the fins 51 into liquid. At this point, the heat is transferred onto the side of the fin 51. The liquefied working fluid is returned to the heat source component 7 by, for example, capillarity. The returned working fluid is evaporated again, and the operation is circulated.

The heat transferred from the heat pipe 6 to the fins 51 is further transferred to the air flowing in the gap between the fins 51, so that the heat source component 7 can efficiently be cooled. The heat pipe 6 is not limited to the configuration in FIG. 5. Alternatively, for example, the heat pipe 6 may be disposed in contact with not the upper end of the fin 51 but the lower end of the fin 51, or each of the two heat pipes may contact individually with the upper end and the lower end of the fin 51. The heat pipe 6 may be in contact with the fins 51 by passing through the fin 51 in the array direction of the fins 51. The heat pipe 6 may be in contact with the upper plate 31 or the lower plate 32. In this case, the upper plate 31 or the lower plate 32 is preferably made of a metal material having thermal conductivity.

In other words, the plurality of fins 51 are made of metal, and the air blower 1 includes the heat pipe 6 connected to the plurality of fins 51 along the array direction of the fins 51. Consequently, the heat of the heat pipe 6 can be transferred to the fins 51, and cooled using the air flowing in the gap between the fins 51.

The side of the heat pipe 6 close to the heat source component 7 is disposed on an upstream side of the airflow F1 generated by the rotation of the impeller 4. Consequently, when the heat of the heat pipe 6 is transmitted onto the side of the fin 51 and cooled using the air flowing in the gap between the fins 51, the heat pipe 6 can effectively be cooled by disposing the heat pipe on the side close to the heat source component 7 on the upstream side where the air flow speed is fast.

A configuration in which the heat pipe is provided for the configurations of the exhaust units 501, 502 in FIG. 3 or 4 may be adopted.

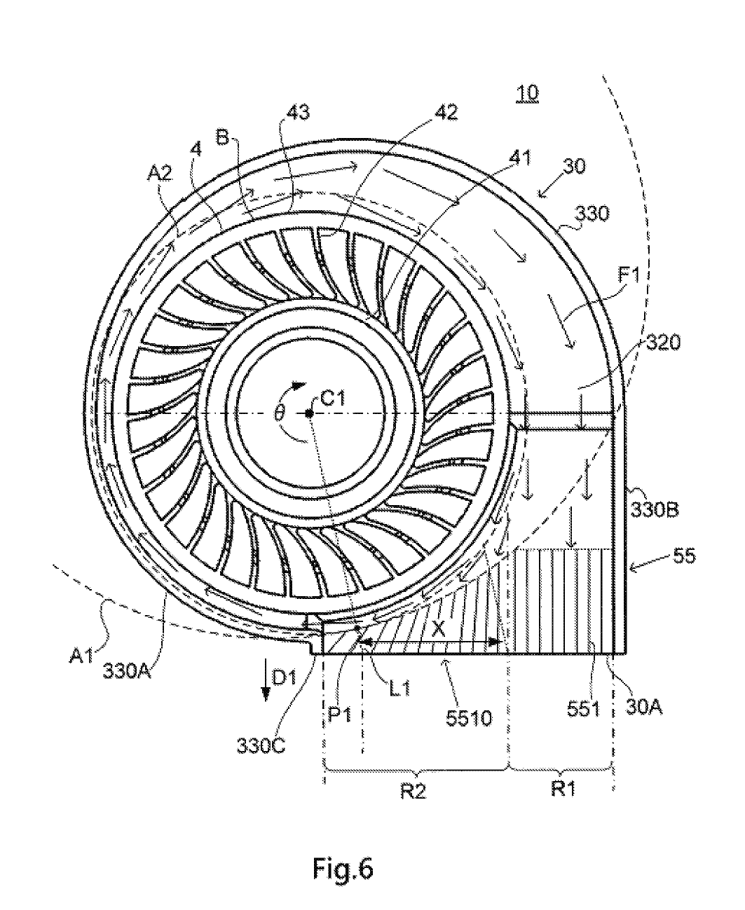

FIG. 6 is a plan view illustrating an air blower 10 according to a third modification viewed from above. In FIG. 6, the upper plate included in a housing 30 is not illustrated for the sake of convenience.

The air blower 10 includes the housing 30, the impeller 4, and a motor unit (not illustrated). The impeller 4 and the motor unit are accommodated in an inner space of the housing 30. The impeller 4 is centered on the central axis C1, and has a configuration similar to that of the embodiment described above. The motor unit is disposed inside the impeller 4, and rotates the impeller 4 about the central axis C1.

The housing 30 includes the upper plate (not illustrated), a lower plate 320, and a side wall 330. The lower plate 320 is located below the impeller 4 and the motor unit, and extends in the radial direction. The motor unit is mounted to the lower plate 320. The side wall 330 extends upward from a peripheral edge of the lower plate 320.

The side wall 330 includes a curved surface 330A and flat surfaces 330B, 330C. The curved surface 330A is gradually separated from the central axis C in the rotational direction θ of the impeller 4, as viewed from above. The flat surface 330B extends linearly from a downstream end of the curved surface 330A in a tangential direction in top view. The flat surface 330C extends radially outward from an upstream end of the curved surface 330A in top view. An air outlet 30A is formed between the downstream end of the flat surface 330B and an outer end of the flat surface 330C.

The upper plate (not illustrated) covers an upper opening of an accommodation space formed by the lower plate 320 and the side wall 330. The air intake hole (air intake portion) passing through the upper plate in the vertical direction is provided in the upper plate. The air intake hole is located above the impeller 4. The air intake hole may be provided in at least one of the upper plate and the lower plate 320.

An exhaust unit 55 is disposed in the first direction D1 with respect to the impeller 4. The exhaust unit 55 includes a plurality of fins 551. Outflow-side ends of the plurality of fins 551 are included in an air outlet 30A. The fin 551 is vertically sandwiched between the upper plate (not illustrated) and the lower plate 320. The exhaust unit 55 includes the upper plate, the lower plate 320, and the fins 551.

When the impeller 4 is rotated in the rotational direction θ by the motor unit, the air is drawn into the housing 30 through the air intake portion, and is blown radially outward along between the blades 42 of the impeller 4. The blown air is regulated by the curved surface 330A and the flat surface 330B, and discharged through the gap between the fins 551 and the air outlet 30A. FIG. 6 illustrates the airflow F1 that is the flow of air generated by the rotation of the impeller 4.

At this point, it is assumed that the first virtual circle A1 is the circle connecting the air-inflow-side ends of a fin group 5510 that is a part of the plurality of fins 551. Assuming that the virtual circle B is the circle connecting the radially outer edges of the blades 42 of the impeller 4 with the central axis C1 as the center, the second virtual circle A2, which is concentric with the virtual circle B and is larger than the virtual circle B in diameter, is connected to the first virtual circle A1 at the virtual circle connection point P1 that is one point. The radius of the first virtual circle A1 is larger than the radius of the second virtual circle A2.

In other words, the air blower 10 of the present embodiment includes the impeller 4 centered on the central axis C1 extending in the vertical direction, the motor unit that rotates the impeller 4 about the central axis C1, and the housing 30 that accommodates the impeller 4. The housing 30 includes the lower plate 320 which covers the lower side of the impeller 4 and to which the motor unit is fixed, the side wall 330 that covers the side of the impeller 4, and the upper plate that covers the upper side of the impeller 4. At least one of the upper plate and the lower plate 320 includes the air intake portion.

The exhaust unit 55 is disposed in the first direction D1 that is the radial component of the impeller 4. The exhaust unit 55 includes the plurality of fins 551. Assuming that the first virtual circle A1 is the circle connecting the ends on the side opposed to the impeller 4 in a fin group 5110 that is a part of the plurality of fins 551 in the first direction D1, and that the second virtual circle A2 is a circle, which is larger than the virtual circle B connecting the radially outer edges of the plurality of blades 42 of the impeller 4 with the central axis C1 as the center in diameter and is connected to the first virtual circle A1 at one point P1, the radius of the first virtual circle A1 is larger than the radius of the second virtual circle A2.

According to this configuration, the distance between the outer end of the blade 42 and the end of the fin 551 is gradually changed to prevent the turbulence of the air in the vicinity of the end of the fin 551, and a loss is reduced in the fin 551, so that the air volume of the air blower 10 can be increased. That is, the noise of the air blower 10 can be reduced by preventing the turbulence of the air, and therefore the air blowing efficiency can be improved. By reducing the distance between the outer edge of the blade 42 and the end of the fin 551, the wind pressure can be enhanced to improve the air blowing force to the fins 551. That is, the amount of air blown from the exhaust unit 55 of the air blower 10 can be improved. The plane area of the fins 551 can be enlarged, and the air blowing efficiency and the cooling efficiency can be enhanced.

In the exhaust unit 55 of FIG. 6, assuming that the first predetermined distance X is the distance from the first line segment L1 toward the upstream side of the airflow F1 in the array direction of the fins 551, the plurality of fins 551 include the first region R1 located on the upstream side of the first predetermined distance X and the second region R2 located on the downstream side of the first predetermined distance X. The feature configuration of the fin 551 in the first region R1 and the second region R2 is similar to that of the embodiment described above.

While the embodiment of the present disclosure has been described above, it is to be understood that various modifications of the embodiment may be made within the scope of the present disclosure.

For example, axial lengths of the plurality of fins may also be a combination of different axial lengths on the air inflow side and the air discharge side.

For example, the present disclosure may be used in a centrifugal fan type air blower.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An air blower comprising:
an impeller centered on a central axis extending in a vertical direction;
a motor that rotates the impeller about the central axis; and
a housing that accommodates the impeller; wherein
the housing includes:
a lower plate which covers a lower side of the impeller and to which the motor is fixed;
a side wall that covers a side of the impeller; and
an upper plate that covers an upper side of the impeller;
at least one of the upper plate and the lower plate includes an air intake portion;
an exhaust extends in a first direction that is a radial component of the impeller;
the exhaust includes a plurality of fins; and
assuming that a first virtual circle is a circle connecting ends on a side opposed to the impeller in the first direction in a fin group that is at least a part of the plurality of fins, and that a second virtual circle is a circle larger than a virtual circle connecting radially outer edges of a plurality of blades of the impeller with the central axis as a center in diameter and is connected to the first virtual circle at one point, a radius of the first virtual circle is larger than a radius of the second virtual circle.

2. The air blower according to claim 1, wherein assuming that a virtual circle connection point is a connection point between the first virtual circle and the second virtual circle:
a distance between a radially outer end of the blade and an arc connecting the ends of the fin group is smallest in a region passing through the central axis and the virtual circle connection point; and
each of an upstream side and a downstream side of an airflow generated by rotation of the impeller from the virtual circle connection point includes an enlarged region where a distance between the radially outer end of the blade and the end of the fin group is increased.

3. The air blower according to claim 2, further comprising a heat pipe connected to the plurality of fins along an array direction of the fins, the fins being made of metal.

4. The air blower according to claim 3, wherein a side at or adjacent to a heat source component of the heat pipe is located on the upstream side of the airflow generated by the rotation of the impeller.

5. The air blower according to claim 2, wherein assuming that a first line segment is a line segment connecting the central axis and the virtual circle connection point, at least a part of the plurality of fins extends in a direction inclined with respect to the first line segment.

6. The air blower according to claim 5, wherein assuming that a first predetermined distance is a distance from the first line segment toward the upstream side of the airflow generated by the rotation of the impeller in an array direction of the fins:
at least a part of the plurality of fins includes a first region located on the upstream side of the first predetermined distance and a second region located on the downstream side of the first predetermined distance; and
the fins are located in the first region and extend in a direction orthogonal to the array direction of the fins.

7. The air blower according to claim 6, wherein the end of the fin in the first region is radially outward of the first virtual circle.

8. The air blower according to claim 6, wherein when the direction in which the fin in the first region extends is 0 degrees, an inclination angle of the fin in the second region is in a range of 0<inclination angle≤5 degrees.

9. The air blower according to claim 8, wherein the inclination angle incrementally changes from 0 to 5 degrees from the upstream side to the downstream side.

10. The air blower according to claim 6, wherein assuming that a second predetermined distance is a distance from the first line segment toward the downstream side of an airflow generated by the rotation of the impeller in the array direction of the fins:
at least a part of the fins in the second region includes a third region located on the downstream side of the second predetermined distance; and
the fins are located in the third region and extend in a direction orthogonal to the array direction of the fins.

11. The air blower according to claim 10, wherein
the side wall includes a tongue protruding toward the impeller; and
the tongue is opposed to the third region in the first direction with a gap therebetween.

12. The air blower according to claim 11, wherein the tongue includes a curved surface extending from an apex opposed to the impeller toward the third region.

13. The air blower according to claim 6, wherein an interval between the fins in the second region is larger than an interval between the fins in the first region.

14. The air blower according to claim 13, wherein assuming that a second predetermined distance is a distance from the first line segment toward the downstream side of an airflow generated by the rotation of the impeller:
at least a part of the fins in the second region includes a third region located on the downstream side of the second predetermined distance; and
an interval between the fins in the third region is smaller than a distance between the fins in a region included in a remaining region in the second region other than the third region.

15. The air blower according to claim 6, further comprising a heat pipe connected to the plurality of fins along an array direction of the fins, the fins being made of metal.

16. The air blower according to claim 15, wherein a side at or adjacent to a heat source component of the heat pipe is on the upstream side of the airflow generated by the rotation of the impeller.
